(19) United States
(12) Patent Application Publication
(10) Pub. No.: US 2024/0355363 A1
(43) Pub. Date: Oct. 24, 2024

(54) BIT LINE CONTACT SCHEME IN A MEMORY SYSTEM STACK

(71) Applicant: Micron Technology, Inc., Boise, ID (US)

(72) Inventors: Mithun Kumar Ramasahayam, Meridian, ID (US); Indra V. Chary, Boise, ID (US); Meng-Wei Kuo, Boise, ID (US)

(21) Appl. No.: 18/630,919

(22) Filed: Apr. 9, 2024

Related U.S. Application Data
(60) Provisional application No. 63/460,579, filed on Apr. 19, 2023.

(51) Int. Cl. G11C 5/06; G11C 16/04; H01L 29/49; H10B 43/27; H10B 43/35

(52) U.S. Cl. CPC G11C 5/063; G11C 16/0483; H01L 29/4966; H10B 43/27; H10B 43/35

(57) ABSTRACT

Methods, systems, and devices for a bit line contact scheme in a memory system stack are described. A memory architecture may include bit lines coupled with bit line contacts, and pillars coupled with circuitry associated with supporting operation of the bit lines. Hybrid plugs may be integrated into the pillars to couple the bit line contacts with the pillars, forming a conductive path between the bit lines and the circuitry. The hybrid plugs may be recessed within the pillars such that the hybrid plugs do not extend through the memory architecture beyond the pillars. The hybrid plugs may include one or more relatively low capacitance, conductive materials, such as a titanium alloy material (e.g., titanium, titanium nitride), a tungsten alloy material (e.g., tungsten, tungsten nitride), or any combination thereof, among other materials.

### CROSS REFERENCE

The present Application for Patent claims priority to U.S. Patent Application No. 63/460,579 by Ramasahayam et al., entitled “BIT LINE CONTACT SCHEME IN A MEMORY SYSTEM STACK,” filed Apr. 19, 2023, which is assigned to the assignee hereof, and which is expressly incorporated by reference in its entirety herein.

### TECHNICAL FIELD

The following relates to one or more systems for memory, including a bit line contact scheme in a memory system stack.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports a bit line contact scheme in a memory system stack in accordance with examples as disclosed herein.

FIGS. 2A, 2B, 2C, 2D, 2E, 2F, 2G, 2H, 2I, and 2J show examples of processing steps that support a bit line contact scheme in a memory system stack in accordance with examples as disclosed herein.

FIG. 3 shows a flowchart illustrating a method or methods that support a bit line contact scheme in a memory system stack in accordance with examples as disclosed herein.

### DETAILED DESCRIPTION

Some memory architectures (e.g., NAND memory) may implement bit lines configured to access memory cells of a memory array located above a stack of materials (e.g., associated with word lines). In some cases, the bit lines may be coupled with respective bit line contacts that extend through the stack of materials to couple the bit lines with circuitry (e.g., below the stack of materials) associated with supporting accessing the memory cells (e.g., a voltage source, a CMOS). For example, a bit line contact may be coupled with one or more pillars (e.g., a string of poly pillars) that are coupled with the circuitry via a plug extending through the stack of materials between the bit line contact and the one or more pillars (e.g., a poly plug associated with aligning the bit line contact with the one or more pillars). In some examples, a capacitance of a bit line may be based on a size and material of a respective plug, such that a relatively large size of the plug or a relatively high capacitance material (e.g., a polysilicon material) may be associated with increasing a capacitance of the respective bit line. In some such examples, a relatively high capacitance of the bit line may adversely affect (e.g., increase) a duration (e.g., a programming time) or an access voltage associated with accessing one or more memory cells of the memory array, resulting in increased latency and power consumption associated with accessing the one or more memory cells, among other issues.

In accordance with examples as described herein, hybrid plugs may be integrated into the pillars to reduce a capacitance associated with implementing plugs extending through the stack of materials, such as a capacitance of a related bit line. For example, a plug extending between a bit line contact and a pillar may be replaced with a hybrid plug recessed within the pillar. In some examples, due to recessing the hybrid plug within the pillar, a size associated with the hybrid plug may be decreased (e.g., compared to other different implementations such as a poly plug associated with aligning the bit line contact with the one or more pillars). In some such examples, reducing the size of the hybrid plug may decrease a capacitance of the plug and as a result, decrease a capacitance of the respective bit line. Additionally, the hybrid plug may include one or more conductive materials (e.g., metal mode titanium, titanium, titanium nitride, tungsten, tungsten nitride), which may have a relatively lower capacitance (e.g., compared to other different implementations), resulting in a decreased capacitance of the respective bit line. Accordingly, implementing the hybrid plug as described herein may decrease the duration or the access voltage associated with accessing one or more memory cells of the memory array, resulting in decreased latency and power consumption associated with accessing the one or more memory cells (e.g., compared to previous implementations), among other advantages.

In addition to applicability in memory systems as described herein, techniques for a bit line contact scheme in a memory system stack may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by integrating hybrid plugs into a memory architecture to support relatively lower bit line capacitance and improved latency for accessing memory cells of the memory architecture, thereby decreasing processing times improving response times, and improving user experience, among other benefits.

In addition to applicability in memory systems as described herein, techniques for a bit line contact scheme in a memory system stack may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by integrating hybrid plugs into a memory architecture to support relatively lower bit line capacitance and decreased power consumption for accessing memory cells of the memory architecture, thereby reducing power consumption of the electronic devices and extending the life of electronic devices, which may reduce electronic waste, among other benefits.

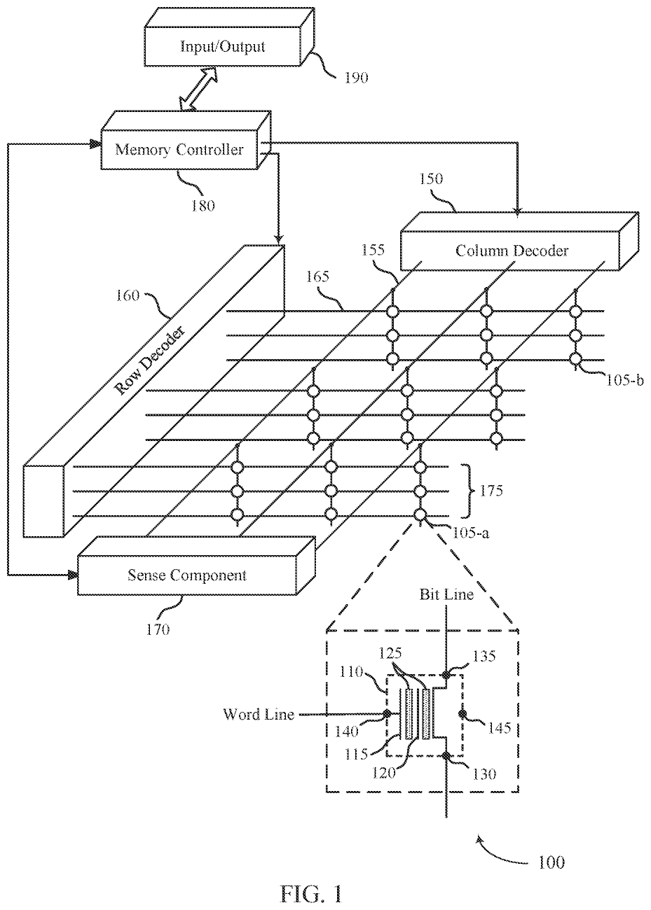

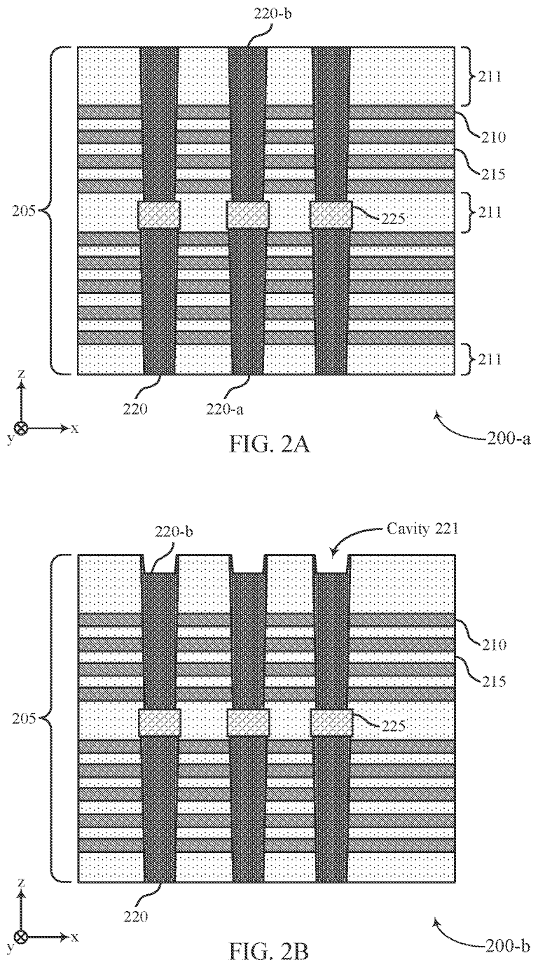

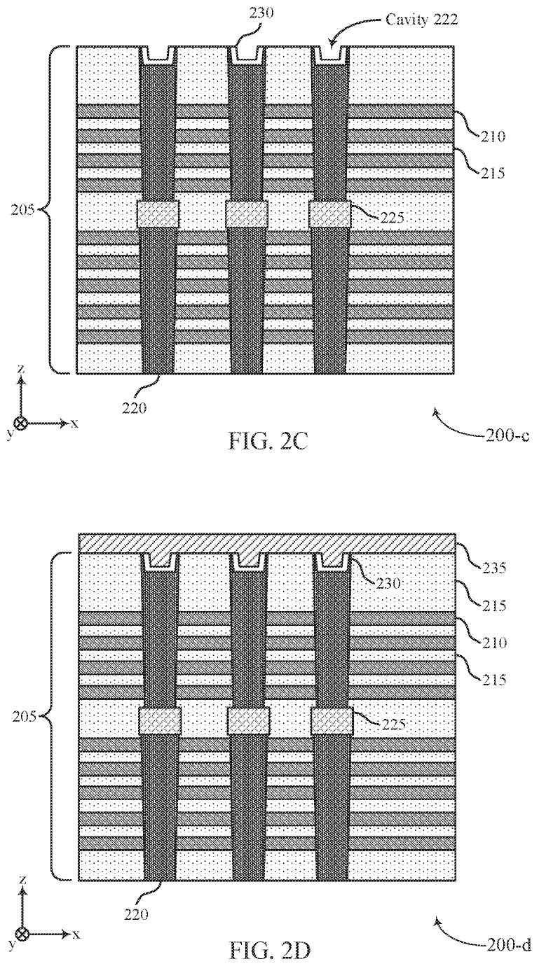

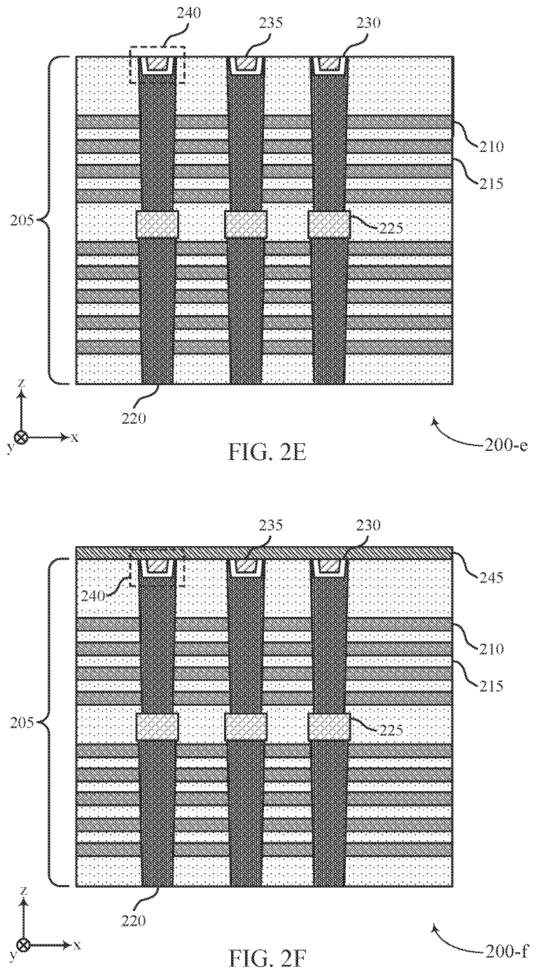

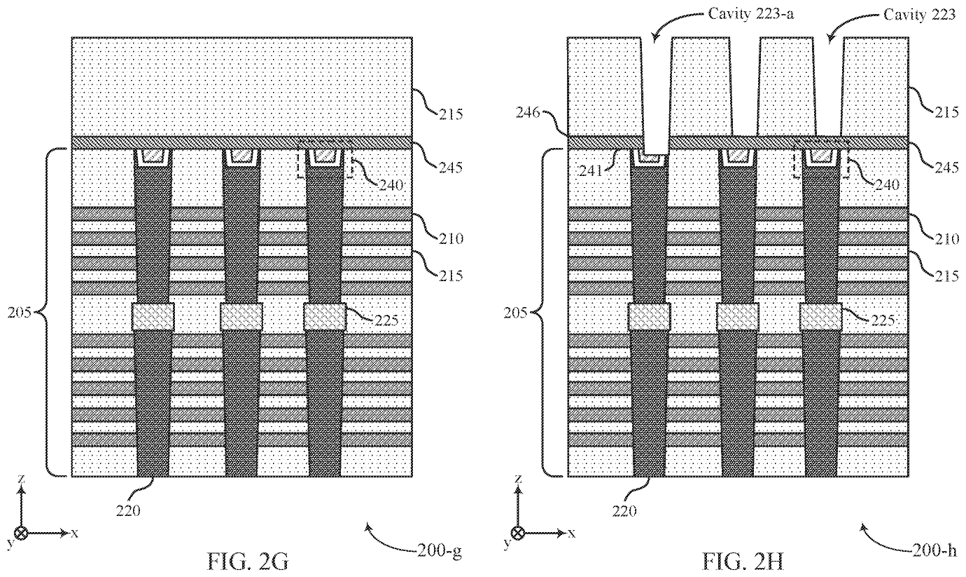

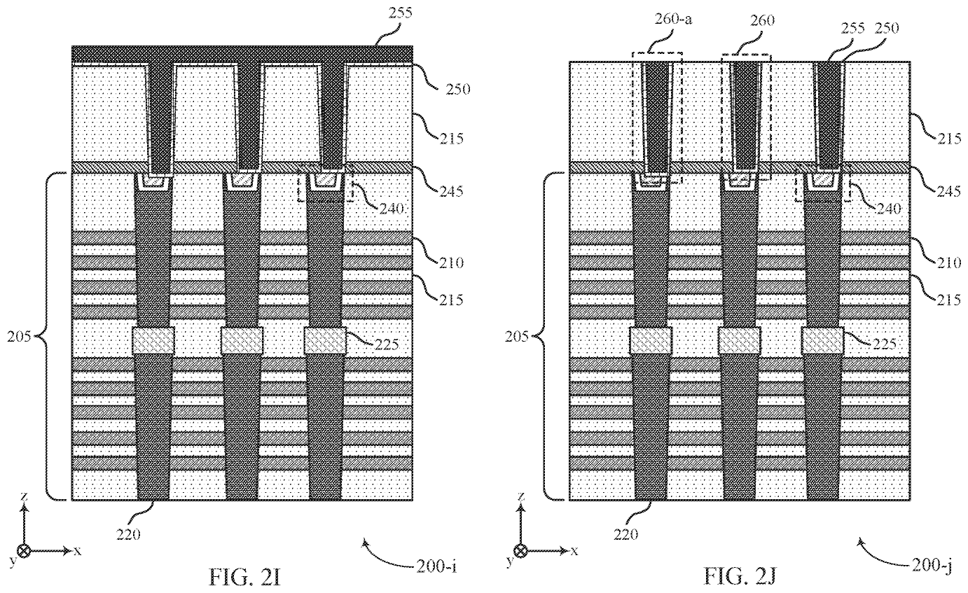

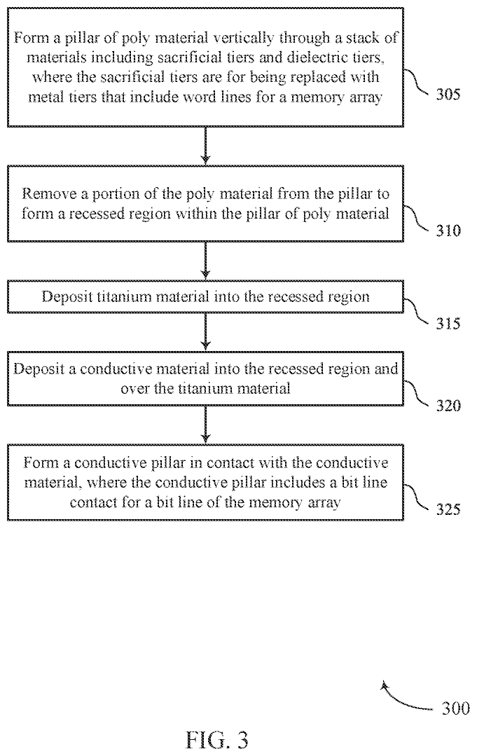

Features of the disclosure are initially described in the context of devices and circuits with reference to FIG. 1. Features of the disclosure are described in the context of processing steps with reference to FIGS. 2A through 2J. These and other features of the disclosure are further illustrated by and described in the context of a flowchart that relates to a bit line contact scheme in a memory system stack with reference to FIG. 3.

FIG. 1 shows an example of a memory device 100 that supports a bit line contact scheme in a memory system stack in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlappingly aligned, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In accordance with examples as described herein, the bit lines 155 may be coupled with respective bit line contacts that extend through (e.g., all the way through) a stack of materials to couple the bit lines 155 with circuitry (e.g., circuitry that may be at least partially or fully below the stack of materials) associated with supporting accessing the memory cells 105 (e.g., a voltage source, a CMOS). For example, a bit line contact may be coupled with one or more pillars (e.g., one or more poly pillars, a string of poly pillars) coupled with the circuitry via a hybrid plug. In some cases, the hybrid plugs may be integrated into the pillars to reduce a capacitance associated with implementing plugs extending through the stack of materials. For example, a plug extending between a bit line contact and a pillar in other different implementation may be replaced with a hybrid plug recessed (e.g., at least partially if not fully) within the pillar. In some examples, due to recessing the hybrid plug within the pillar, a size associated with the hybrid plug may be decreased (e.g., compared to other different implementations). In some such examples, reducing the size of the hybrid plug may decrease a capacitance of the plug, resulting in a decreased capacitance of the respective bit line 155. Additionally, the hybrid plug may include one or more conductive materials (e.g., metal mode titanium, titanium, titanium nitride, tungsten, tungsten nitride) which may have a relatively lower capacitance (e.g., compared to previous implementations), resulting in a decreased capacitance of the respective bit line 155. Accordingly, implementing the hybrid plug as described herein may decrease the duration or the access voltage associated with accessing one or more memory cells of the memory array, resulting in decreased latency and power consumption associated with accessing one or more memory cells 105 (e.g., compared to previous implementations), among other advantages.

In addition to applicability in memory systems as described herein, techniques for a bit line contact scheme in a memory system stack may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by integrating hybrid plugs into a memory architecture to support relatively lower bit line capacitance and improved latency for accessing memory cells of the memory architecture, thereby decreasing processing times improving response times, and improving user experience, among other benefits.

In addition to applicability in memory systems as described herein, techniques for a bit line contact scheme in a memory system stack may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by integrating hybrid plugs into a memory architecture to support relatively lower bit line capacitance and decreased power consumption for accessing memory cells of the memory architecture, thereby reducing power consumption of the electronic devices and extending the life of electronic devices, which may reduce electronic waste, among other benefits.

FIGS. 2A through 2J show examples of processing steps 200 (e.g., processing steps 200-a through 200-f) that support a bit line contact scheme in a memory system stack in accordance with examples as disclosed herein. The processing steps 200 may illustrate aspects of manufacturing operations for fabricating aspects of a memory architecture, which may be implemented by a memory device 100, as described with reference to FIG. 1, or a memory system. For illustrative purposes, aspects of the memory architecture may be described with reference to an x-direction, a y-direction, and a z-direction of the illustrated coordinate system. For example, the processing steps 200 may illustrate various cross-sectional views of a memory architecture in an xz-plane. In some examples, the z-direction may be illustrative of a direction orthogonal to a surface of a substrate (e.g., a surface in an xy-plane, a surface above which components may be formed), and each of the related regions, illustrated by their respective cross section in the xz-plane, may extend for some distance along the y-direction (e.g., into the page).

Although the processing steps 200 illustrate examples of relative dimensions and quantities of various features, aspects of the memory architecture may be implemented with other relative dimensions or quantities of such features in accordance with examples as disclosed herein. In the following description of the processing steps 200, some methods, techniques, processes, and operations may be performed in different orders or at different times. Further, some operations may be left out of the processing steps 200, or other operations may be added to the processing steps 200. The processing steps 200 may illustrate operations associated with forming hybrid plugs recessed within pillars (e.g., coupling bit line contacts to supporting circuitry) to reduce a capacitance (e.g., of bit lines) otherwise associated with implementing plugs extending through a stack of materials.

Operations illustrated in and described with reference to FIGS. 2A through 2J may be performed by a manufacturing system, such as a semiconductor fabrication system configured to perform additive operations such as deposition, bonding, and/or coupling; subtractive operations such as etching, trenching, planarizing, and/or polishing; and supporting operations such as masking, patterning, photolithography, and/or aligning; among other operations that support the described techniques. In some examples, operations performed by such a manufacturing system may be supported by a controller, such as a process controller, or its components as described herein.

FIG. 2A illustrates a first processing step 200-a for forming a stack of materials 205. For example, forming the stack of materials 205 may include forming (e.g., depositing) alternating layers (e.g., tiers) of a sacrificial material 210 and a dielectric material 215. In some examples, the dielectric material 215 may include an oxide material and the sacrificial material 210 may include a temporary material (e.g., a placeholder material such as a nitride material) which may later be replaced with a conductive material (e.g., tungsten) to form word lines of the memory architecture. For example, the sacrificial material 210 may be metallized (e.g., exhumed and replaced with a metal material) to form word lines at a later processing step (e.g., after the processing steps 200). The alternating layers may be deposited (e.g., layer by layer) in xy-planes above circuitry (e.g., CMOS, voltage source, decoders) associated with supporting operations of the memory architecture and may in some examples alternate along a direction, such as the z-direction. Although the alternating layers may be deposited above the circuitry, in some examples, one or more other intermediate materials may be deposited between the circuitry and the alternating layers. In some cases, the dielectric material 215 may be deposited in relatively thicker layers (e.g., along the z-direction) in regions 211 of the memory architecture compared to other thinner layers in different regions 211.

The first processing step 200-a may include forming pillars 220 (e.g., channels) extending through the stack of materials 205 (e.g., along the z-direction). The pillars 220 may include a semiconductor poly material (e.g., from Group IV, compound semiconductors including elements from Group III and V or elements from Group II and VI), such as polysilicon, poly SiGe, poly GaAs, poly InGaAs, among other materials. In some examples, the pillars 220 may include a dielectric material (e.g., an oxide material) that may line the pillars 220 (e.g., exterior to the semiconductor poly material). In some examples, the pillars 220 may include a hollow region within the semiconductor poly material extending through the pillars 220 (e.g., along the z-direction). In some such examples, the hollow region may be filled with a cell film material.

In some cases, the pillars 220 may include strings of pillars 220 which each may include one or more pillars 220 aligned along a direction such as the z-direction, and coupled via an interconnect 225 (e.g., a plug). For example, a string of the pillars 220 may include a pillar 220-a and a pillar 220-b coupled via an interconnect 225. In some cases, the interconnect 225 may be associated with aligning the respective pillars 220 during forming the pillars 220. In some examples, the interconnect 225 may include a semiconductor poly material (e.g., from Group IV, compound semiconductors), such as polysilicon, poly SiGe, poly GaAs, poly InGaAs, among other materials. In other cases, the pillars 220 may be formed such that a pillar 220-a may be directly coupled (e.g., contacting) with a pillar 220-b (e.g., without an interconnect 225). The strings of pillars 220 may be associated with coupling bit lines (e.g., above the stack of materials 205 along the z-direction, not shown) of the memory architecture with circuitry (e.g., CMOS, voltage source, decoders) associated with supporting operations of the memory architecture. Although the first processing step 200-a is described as a “first” processing step, this step may in some examples be preceded by other supporting processing steps and may or may not be an initial processing step of the global process. Other processing steps may be preceded by or followed by one or more other processing steps in some examples.

FIG. 2B illustrates a second processing step 200-b for forming cavities 221 (e.g., voids) within the pillars 220. For example, the second processing step 200-b may include subjecting the pillars 220-b to a removal operation to recess top portions of the pillars 220 (e.g., respective to the z-direction), where recessing the top portions of the pillars 220 forms the cavities 221 (e.g., a respective cavity 221 above a respective pillar 220). In some examples, the removal operation may be an etching operation (e.g., a dry etch, a wet etch). In some implementations, the cavities 221 may be tapered (as part of the removal operation and/or separately) such that the cavities 221 are wider (e.g., along the x-direction) at a first region, such as a top region (e.g., along the z-direction) of the cavities 221 than at a second region, such as a bottom region (e.g., along the z-direction) of the cavities 221. Although the second processing step 200-b is described as a “second” processing step, this step may in some examples be preceded or followed by other supporting processing steps, and may or may not be a “second” processing step of the global process.

FIG. 2C illustrates a third processing step 200-c for forming a liner 230 in the cavities 221. For example, the third processing step 200-c may include depositing the liner 230 into the cavities 221 (e.g., at least into the cavities 221 if not across other portions of the stack of materials) with a thickness, such as a uniform thickness, that may extend at least partially out from each side of the cavities 221 (e.g., that extends at least partially out at the top of the cavity from the stack of materials). The liner 230 may be formed such that cavities 222 (e.g., which may be smaller than the cavities 221, voids) may exist in the recessed top portion of the pillars 220 (e.g., the pillars 220-b) after the forming the liner 230. In some implementations, the liner 230 may be at least partially removed (e.g., planarized) after the liner 230 is deposited into the cavities 221 such that a top portion (in the z direction) may be planar. In some examples, the liner 230 may be a conductive material (e.g., a first conductive material, a metal or metal alloy) associated with a relatively low capacitance (e.g., relatively high ohmic contact), such as a titanium alloy material (e.g., titanium, titanium silicon, titanium nitride, metal mode titanium), a tungsten alloy material (tungsten, tungsten nitride), one or more other materials (e.g., Co, Pt, Au, Ag), or any combination thereof. In some cases, one or more other intermediate materials may be deposited into the cavities 221 prior to forming the liner 230 in the cavities 221. Although the third processing step 200-c is described as a “third” processing step, this step may in some examples be preceded or followed by other supporting processing steps, and may or may not be a “third” processing step of the global process.

FIG. 2D illustrates a fourth processing step 200-d for forming a conductive material 235 (e.g., a second conductive material). For example, the fourth processing step 200-d may include depositing the conductive material 235 into the cavities 222. In some cases, the conductive material 235 may be deposited such that a portion of the conductive material 235 is deposited above the dielectric material 215 in a top region (e.g., region 211) of the stack of materials 205 (e.g., along the z-direction). In some examples, depositing the conductive material 235 may include performing a chemical vapor deposition operation and/or a plasma vapor deposition operation, among other deposition operations.

In some cases, the conductive material 235 may include a metal or metal alloy associated with a relatively low capacitance (e.g., relatively high ohmic contact), such as a titanium alloy material (e.g., titanium, titanium silicon, titanium nitride, metal mode titanium), a tungsten alloy material (tungsten, tungsten nitride), or any combination thereof, among other materials (e.g., Co, Pt, Au, Ag). For example, the liner 230 may include titanium or titanium nitride, and the conductive material 235 may include tungsten (e.g., each sequentially deposited). In another example, the liner 230 may include a titanium alloy material (e.g., metal mode titanium), and the conductive material 235 may include tungsten nitride and titanium nitride (e.g., each sequentially deposited). Although the conductive material 235 may be deposited in contact with the liner 230, in some examples the conductive material 235 may be not in contact with the liner 230 (may be within the cavities 221, but may be separated from the liner 230 by one or more other intermediate materials). Although the fourth processing step 200-d is described as a “fourth” processing step, this step may in some examples be preceded or followed by other supporting processing steps, and may or may not be a “fourth” processing step of the global process.

FIG. 2E illustrates a fifth processing step 200-e for removing the conductive material 235. For example, the fifth processing step 200-e may include removing (e.g., planarizing) a portion of the conductive material 235 extending above the dielectric material 215 at a top region of the stack of materials (e.g., region 211). In some cases, removing (e.g., planarizing) the conductive material 235 may include planarizing the conductive material 235, the liner 230, and/or the dielectric material 215, or any combination thereof, such that the conductive material 235, the liner 230 and the dielectric material 215 may be coplanar (e.g., along an xy-plane). The conductive material 235 and the liner 230 may form the hybrid plug 240, such that each recessed portion of a respective pillar may include a hybrid plug 240. Although the fifth processing step 200-e is described as a “fifth” processing step, this step may in some examples be preceded or followed by other supporting processing steps, and may or may not be a “fifth” processing step of the global process.

FIG. 2F illustrates a sixth processing step 200-f for forming a cap 245. For example, the sixth processing step 200-f may include depositing the cap 245 (e.g., a layer of material) above (e.g., along the z-direction) the hybrid plugs 240 and the dielectric material 215, in an xy-plane. In some cases, the cap 245 may be associated with, among other aspects, preventing a removal operation (e.g., an etching operation) from accidentally contacting the hybrid plugs 240, or the dielectric material 215, or both, which may adversely affect operation of the memory architecture. For example, the cap 245 may include a silicon oxycarbonitride (SiOCN) material or a carbon doped silicon nitride material, which may be resistant to an etching operation that may otherwise remove the hybrid plugs 240, or the dielectric material 215, or both. Although the cap 245 may be deposited above and in contact with the hybrid plugs 240 and the dielectric material 215, in some examples the cap 245 may be deposited above and not in contact with the hybrid plugs 240 and the dielectric material 215 (may be above the hybrid plugs 240 and the dielectric material 215, but may be separated from the hybrid plugs 240 and the dielectric material 215 by one or more other intermediate materials). Although the sixth processing step 200-f is described as a “sixth” processing step, this step may in some examples be preceded or followed by other supporting processing steps, and may or may not be a “sixth” processing step of the global process.

FIG. 2G illustrates a seventh processing step 200-g for depositing the dielectric material 215 above the cap 245 (e.g., along the z-direction). In some examples, the dielectric material 215 may be planarized after depositing the dielectric material 215 above the cap 245. Although the dielectric material 215 may be deposited above and in contact with the cap 245, in some examples the dielectric material 215 may be deposited above and not in contact with the cap 245 (may be above the cap 245, but may be separated from the cap 245 by one or more other intermediate materials). Although the seventh processing step 200-g is described as a “seventh” processing step, this step may in some examples be preceded or followed by other supporting processing steps, and may or may not be a “seventh” processing step of the global process.

FIG. 2H illustrates a eighth processing step 200-h for forming cavities 223 (e.g., voids) in the dielectric material 215. For example, the eighth processing step 200-h may include subjecting the dielectric material 215 to a removal operation to recess portions of the dielectric material 215 down to (e.g., at least to) a top surface 246 of the cap 245, where recessing the portions of the dielectric material 215 forms the cavities 221. In some examples, the removal operation may be a wet etching operation (e.g., a wet etch), such that the dielectric material 215 may be exposed to a wet etchant that may remove the portions of the dielectric material 215. However, in some such examples, the cap 245 may be resistant to the wet etchant such that the cap 245 may not be removed (e.g., may not be partially removed, may not be fully removed) during etching the dielectric material 215, and the etching operation may, in some examples, stop at or near the top surface 246 of the cap 245. In some implementations, the cavities 223 may be tapered such that the cavities 223 are wider (e.g., along the x-direction) at a first region such as a top region (e.g., along the z-direction) of the cavities 223 than at a second region such as a bottom region (e.g., along the z-direction) of the cavities 223.

The eighth processing step 200-h may additionally or alternatively include extending the cavities 223 to or even at least partially in (e.g., not shown) the hybrid plugs 240. For example, the eighth processing step 200-h may include subjecting the cap 245 to a removal operation (an additional removal operation or as part of a same removal operation) to remove portions of the cap 245 down to, near, or even past (in some examples) a top surface 241 of the hybrid plugs 240, where removing the portions of the cap 245 may extend the cavities 223 in the z direction. In some examples, the removal operation may be a dry etching operation (e.g., a dry etch, a punch), such that the portions of the cap 245 may be mechanically removed by one or more processes. In some examples, the cavities 223 (e.g., one or more of the cavities 223) may be formed such that they extend in the z-direction to a depth at least partially overlapping with the hybrid plugs 240 or the pillars 220. For example, cavity 223-a may be an example of the cavities 223 extending at least partially into the hybrid plugs 240. In some implementations, the cavities 223 may be formed such that they at least partially overlap with the hybrid plugs 240 or the pillars 220 (e.g., along the x-direction and the y-direction). Although the eighth processing step 200-h is described as an “eighth” processing step, this step may in some examples be preceded or followed by other supporting processing steps, and may or may not be an “eighth” processing step of the global process.

FIG. 2I illustrates a ninth processing step 200-i for forming a conductive material 250 (e.g., a fourth conductive material) and a conductive material 255 (e.g., a third conductive material). For example, the ninth processing step 200-i may include depositing the conductive material 250 into the cavities 223. In some cases, the conductive material 250 may be deposited such that a portion of the conductive material 250 is deposited above the dielectric material 215 formed at the seventh processing step 200-g (e.g., above the stack of materials 205 along the z-direction). The conductive material 250 may be a liner for the conductive material 255 and may have a thickness (e.g., a uniform thickness, a non-uniform thickness) that extends at least partially out from each side of the cavities 223 and above the dielectric material 215. However, the conductive material 250 may be formed such that cavities may exist in the recessed portions of the dielectric material 215 (e.g., exterior to the conductive material 250). Although the conductive material 250 may be deposited above and in contact with the dielectric material 215, in some examples the conductive material 250 may be deposited above and not in contact with the dielectric material 215 (may be above the dielectric material 215, but may be separated from the cap 245 by one or more other intermediate materials).

Additionally, the ninth processing step 200-i may include depositing the conductive material 255 into the cavities 223 above the conductive material 255. For example, the conductive material 255 may be deposited such that the cavities remaining from depositing the conductive material 250 into the cavities 223 may be filled with the conductive material 255. Further, a portion of the conductive material 255 may be deposited above the conductive material 250 which is above the dielectric material 215 formed at the seventh processing step 200-g (e.g., above the stack of materials 205 along the z-direction). In some examples, depositing the conductive material 250 and the conductive material 255 may include performing a chemical vapor deposition operation, and/or a plasma vapor deposition operation, among other deposition operations. Although the conductive material 255 may be deposited above and in contact with the conductive material 250, in some examples the conductive material 255 may be deposited above and not in contact with the conductive material 250 (may be above the conductive material 250, but may be separated from the conductive material 250 by one or more other intermediate materials).

In some cases, the conductive material 250 may include a metal or metal alloy associated with a relatively low capacitance (e.g., relatively high ohmic contact), such as a titanium alloy material (e.g., titanium, titanium silicon, titanium nitride, metal mode titanium), a tungsten alloy material (tungsten, tungsten nitride), or any combination thereof, among other materials (e.g., Co, Pt, Au, Ag). In some cases, the conductive material 255 may include a metal or metal alloy associated with a relatively low capacitance (e.g., relatively high ohmic contact), such as a titanium alloy material (e.g., titanium, titanium silicon, titanium nitride, metal mode titanium), a tungsten alloy material (tungsten, tungsten nitride), or any combination thereof, among other materials (e.g., Co, Pt, Au, Ag). For example, the conductive material 250 may include titanium nitride, and the conductive material 250 may include tungsten (e.g., each sequentially deposited). In some implementations, a dielectric material (e.g., an oxide material) may be deposited before the conductive material 250, and may function as a liner for the conductive material 250 and the conductive material 255.

In some cases, the conductive material 250 and the conductive material 255 may be deposited into the cavities 223 such that the conductive material 250 and the conductive material 255 may share a shape of the cavities 223. In some such cases, the conductive material 255 and the conductive material 255 may be deposited to a depth contacting or extending at least partially into the hybrid plugs 240 or the pillars 220. For example, the conductive material 250 and the conductive material 255 in the cavity 223-a may be deposited such that the conductive material 255 and the conductive material 255 at least partially extend into the respective hybrid plug 240. Although the ninth processing step 200-i is described as a “ninth” processing step, this step may in some examples be preceded or followed by other supporting processing steps, and may or may not be a “ninth” processing step of the global process.

FIG. 2J illustrates a tenth processing step 200-j for removing the conductive material 250 and the conductive material 255. For example, the tenth processing step 200-j may include removing (e.g., planarizing) a portion of the conductive material 250 and a portion of the conductive material 255 extending above the dielectric material 215 formed at the seventh processing step 200-g (e.g., above the stack of materials 205 along the z-direction). In some cases, removing (e.g., planarizing) the conductive material 250 and the conductive material 255 may include planarizing the dielectric material 215 such that the conductive material 250, the conductive material 255, and the dielectric material 215 are coplanar (e.g., along an xy-plane). The conductive material 250 and the conductive material 255 may form bit line contacts 260 (e.g., conductive pillars), which may be coupled with bit lines (e.g., not shown, above the bit line contacts 260 along the z-direction) of the memory architecture. In some cases, after forming the bit line contacts 260, the sacrificial material 210 may be replaced with conductive material to form the word lines of the memory architecture. In some cases, the bit line contacts 260 may be formed such that the bit line contacts 260 contacts a top surface of the hybrid plugs 240 or the pillars 220 (e.g., along the z-direction). However, in other cases, the bit line contacts 260 may be formed such that the bit line contacts 260 extend at least partially into the hybrid plugs 240 or the pillars 220 (e.g., along the z-direction). For example, a bit line contact 260-a may be recessed at least partially into the respective hybrid plug 240. In some implementations, the bit line contacts 260 may be formed such that each bit line contact 260 may share a same height along the z-direction, or a different height along the z-direction. Although the tenth processing step 200-j is described as a “tenth” processing step, this step may in some examples be preceded or followed by other supporting processing steps, and may or may not be a “tenth” processing step of the global process.

In accordance with examples as described herein, implementing the hybrid plugs 240 to couple the bit line contacts 260 with the pillars 220 may support a relatively lower capacitance between the bit lines (e.g., coupled with the bit line contacts 260) and the supporting circuitry (e.g., coupled with the pillars 220) of the memory architecture. For example, by integrating the hybrid plugs 240 within the pillars 220, a size of the hybrid plugs 240 may be reduced (e.g., compared to previous implementations), which may reduce a capacitance of the hybrid plugs, thereby reducing a capacitance of the respective bit lines. Additionally, by implementing the hybrid plugs 240 with conductive materials associated with a relatively lower capacitance (e.g., compared to previous implementations) may further reduce a capacitance of the respective bit lines. In some cases, reducing a capacitance of the bit lines may support a relatively lower access voltage (e.g., programming voltage) or a relatively shorter duration (e.g., programming time) associated with accessing memory cells of the memory architecture (e.g., via the bit lines). Therefore, the memory architecture may benefit from reduced power consumption and decreased latency associated with performing access operations.

FIG. 3 shows a flowchart illustrating a method 300 that support a bit line contact scheme in a memory system stack in accordance with examples as disclosed herein. The operations of method 300 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 305, the method may include forming a pillar of poly material vertically through a stack of materials including sacrificial tiers and dielectric tiers, where the sacrificial tiers are for being replaced with metal tiers that include word lines for a memory array. At 310, the method may include removing a portion of the poly material from the pillar to form a recessed region within the pillar of poly material.

At 315, the method may include depositing a first conductive material (e.g., titanium) into the recessed region. At 320, the method may include depositing a second conductive material into the recessed region and over the first conductive material. At 325, the method may include forming a conductive pillar in contact with the second conductive material, where the conductive pillar includes a bit line contact for a bit line of the memory array.

In some examples, the method may include replacing, after forming the conductive pillar, the sacrificial tiers with the metal tiers that include the word lines for the memory array.

In some examples, the first conductive material includes a titanium alloy and the second conductive material includes tungsten nitride. In some such examples, the method may include depositing titanium nitride in contact with the tungsten nitride.

In some examples, the first conductive material includes titanium nitride and the second conductive material includes tungsten.

In some examples, the method may include depositing silicon oxycarbonitride (SiOCN) over the second conductive material, where the conductive pillar is formed after depositing the SiOCN.

In some examples, the method may include removing a portion of the SiOCN that is over the second conductive material, where the conductive pillar is formed after removing the portion of the SiOCN.

In some examples, the method may include depositing an oxide material over the SiOCN, where the second conductive material is formed after depositing the oxide material.

In some examples, the method may include removing a portion of the oxide material that is over the second conductive material to form a cavity, where the conductive pillar is formed after removing the portion of the oxide material.

In some examples, the conductive pillar includes a third conductive material separated from the first conductive material, the second conductive material, the SiOCN, and the oxide material by a fourth conductive material.

In some examples, an apparatus (e.g., a manufacturing system) as described herein may perform a method or methods, such as the method 300. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a pillar of poly material vertically through a stack of materials including sacrificial tiers and dielectric tiers, where the sacrificial tiers are for being replaced with metal tiers that include word lines for a memory array; removing a portion of the poly material from the pillar to form a recessed region within the pillar of poly material; depositing a first conductive material into the recessed region; depositing a second conductive material into the recessed region and over the first conductive material; and forming a conductive pillar in contact with the second conductive material, where the conductive pillar includes a bit line contact for a bit line of the memory array.

Aspect 2: The method or apparatus of aspect 1, further including operations, features, circuitry, logic, means, or instructions, or any combination thereof for replacing, after forming the conductive pillar, the sacrificial tiers with the metal tiers that include the word lines for the memory array.

Aspect 3: The method or apparatus of any of aspects 1 through 2, where the first conductive material includes a titanium alloy and the second conductive material includes tungsten nitride and the method, apparatuses, and non-transitory computer-readable medium further includes operations, features, circuitry, logic, means, or instructions, or any combination thereof for depositing titanium nitride in contact with the tungsten nitride.

Aspect 4: The method or apparatus of any of aspects 1 through 3, where the first conductive material includes titanium nitride and the second conductive material includes tungsten.

Aspect 5: The method or apparatus of any of aspects 1 through 4, further including operations, features, circuitry, logic, means, or instructions, or any combination thereof for depositing silicon oxycarbonitride (SiOCN) over the second conductive material, where the conductive pillar is formed after depositing the SiOCN.

Aspect 6: The method or apparatus of aspect 5, further including operations, features, circuitry, logic, means, or instructions, or any combination thereof for removing a portion of the SiOCN that is over the second conductive material, where the conductive pillar is formed after removing the portion of the SiOCN.

Aspect 7: The method or apparatus of any of aspects 5 through 6, further including operations, features, circuitry, logic, means, or instructions, or any combination thereof for depositing an oxide material over the SiOCN, where the second conductive material is formed after depositing the oxide material.

Aspect 8: The method or apparatus of aspect 7, further including operations, features, circuitry, logic, means, or instructions, or any combination thereof for removing a portion of the oxide material that is over the second conductive material to form a cavity, where the conductive pillar is formed after removing the portion of the oxide material.

Aspect 9: The method or apparatus of any of aspects 7 through 8, where the conductive pillar includes a third conductive material separated from the first conductive material, the second conductive material, the SiOCN, and the oxide material by a fourth conductive material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: An apparatus, including: a pillar of poly material disposed vertically through a stack of materials including conductive tiers and dielectric tiers, where the conductive tiers include word lines for a memory array; a concave liner including a first conductive material and disposed within the pillar; a second conductive material that at least partially fills a void formed by the concave liner; and a conductive pillar in contact with the second conductive material, where the conductive pillar includes a bit line contact for a bit line of the memory array.

Aspect 11: The apparatus of aspect 10, where the second conductive material includes titanium nitride, the apparatus further including: a layer of tungsten nitride that is below the titanium nitride and that at least partially fills the concave liner.

Aspect 12: The apparatus of any of aspects 10 through 11, where the second conductive material includes tungsten.

Aspect 13: The apparatus of any of aspects 10 through 12, further including: an oxide material that at least partially surrounds the pillar of poly material and that at least partially surrounds the conductive pillar.

Aspect 14: The apparatus of any of aspects 10 through 13, further including: a layer of silicon oxycarbonitride (SiOCN) disposed over the second conductive material, where the conductive pillar extends through the layer of SiOCN.

Aspect 15: The apparatus of any of aspects 10 through 14, where the conductive pillar includes a third conductive material at least partially surrounded by a fourth conductive material.

Aspect 16: The apparatus of any of aspects 10 through 15, where the third conductive material includes tungsten and the fourth conductive material includes titanium nitride.

An apparatus is described. The following provides an overview of aspects of the apparatus as described herein:

Aspect 17: An apparatus, including: a pillar of poly material disposed vertically through a stack of materials including conductive tiers that include word lines for a memory array; an oxide material that at least partially surrounds the pillar of poly material; a first conductive material that is disposed within the pillar and is at least partially surrounded by the oxide material; a second conductive material disposed within the first conductive material; and a bit line contact for a bit line of the memory array in contact with the second conductive material.

Aspect 18: The apparatus of aspect 17, where the first conductive material includes a titanium alloy and the second conductive material includes titanium nitride, the apparatus further including: tungsten nitride disposed between the titanium alloy and the titanium nitride.

Aspect 19: The apparatus of any of aspects 17 through 18, where the first conductive material includes a titanium nitride and the second conductive material includes tungsten.

Aspect 20: The apparatus of any of aspects 17 through 19, further including: a layer of silicon oxycarbonitride (SiOCN) disposed within the oxide material and above the first conductive material, the second conductive material, and the conductive tiers, where the bit line contact extends through the layer of SiOCN to contact the second conductive material.

Aspect 21: The apparatus of any of aspects 17 through 20, where the bit line contact includes a conductive pillar including a third conductive material that is separated from the second conductive material by a fourth conductive material.

Aspect 22: The apparatus of any of aspects 17 through 21, further including: dielectric tiers disposed in between the conductive tiers and at least partially surrounding the pillar of poly material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as any combination of computing devices (e.g., any combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a pillar of poly material disposed vertically through a stack of materials comprising conductive tiers and dielectric tiers, wherein the conductive tiers comprise word lines for a memory array;
a concave liner comprising a first conductive material and disposed within the pillar;
a second conductive material that at least partially fills a void formed by the concave liner; and
a conductive pillar in contact with the second conductive material, wherein the conductive pillar comprises a bit line contact for a bit line of the memory array.

2. The apparatus of claim 1, wherein the second conductive material comprises titanium nitride, the apparatus further comprising:
a layer of tungsten nitride that is below the titanium nitride and that at least partially fills the concave liner.

3. The apparatus of claim 1, wherein the second conductive material comprises tungsten, the apparatus further comprising:
an oxide material that at least partially surrounds the pillar of poly material and that at least partially surrounds the conductive pillar.

4. The apparatus of claim 1, further comprising:
a layer of silicon oxycarbonitride (SiOCN) disposed over the second conductive material, wherein the conductive pillar extends through the layer of SiOCN.

5. The apparatus of claim 1, wherein the conductive pillar comprises a third conductive material at least partially surrounded by a fourth conductive material.

6. The apparatus of claim 5, wherein the third conductive material comprises tungsten and the fourth conductive material comprises titanium nitride.

7. A method, comprising:
forming a pillar of poly material vertically through a stack of materials comprising sacrificial tiers and dielectric tiers, wherein the sacrificial tiers are for being replaced with metal tiers that comprise word lines for a memory array;
removing a portion of the poly material from the pillar to form a recessed region within the pillar of poly material;
depositing a first conductive material into the recessed region;
depositing a second conductive material into the recessed region and over the first conductive material; and
forming a conductive pillar in contact with the second conductive material, wherein the conductive pillar comprises a bit line contact for a bit line of the memory array.

8. The method of claim 7, further comprising:
replacing, after forming the conductive pillar, the sacrificial tiers with the metal tiers that comprise the word lines for the memory array.

9. The method of claim 7, wherein the first conductive material comprises a titanium alloy and the second conductive material comprises tungsten nitride, the method further comprising:
depositing titanium nitride in contact with the tungsten nitride.

10. The method of claim 7, wherein the first conductive material comprises titanium nitride, and wherein the second conductive material comprises tungsten.

11. The method of claim 7, further comprising:
depositing silicon oxycarbonitride (SiOCN) over the second conductive material, wherein the conductive pillar is formed after depositing the SiOCN.

12. The method of claim 11, further comprising:
removing a portion of the SiOCN that is over the second conductive material, wherein the conductive pillar is formed after removing the portion of the SiOCN.

13. The method of claim 11, further comprising:
depositing an oxide material over the SiOCN, wherein the second conductive material is formed after depositing the oxide material.

14. The method of claim 13, further comprising:
removing a portion of the oxide material that is over the second conductive material to form a cavity, wherein the conductive pillar is formed after removing the portion of the oxide material.

15. The method of claim 13, wherein the conductive pillar comprises a third conductive material separated from the first conductive material, the second conductive material, the SiOCN, and the oxide material by a fourth conductive material.

16. An apparatus, comprising:
a pillar of poly material disposed vertically through a stack of materials comprising conductive tiers that comprise word lines for a memory array;
an oxide material that at least partially surrounds the pillar of poly material;
a first conductive material that is disposed within the pillar and is at least partially surrounded by the oxide material;
a second conductive material disposed within the first conductive material; and
a bit line contact for a bit line of the memory array in contact with the second conductive material.

17. The apparatus of claim 16, wherein the first conductive material comprises a titanium alloy and the second conductive material comprises titanium nitride, the apparatus further comprising:
tungsten nitride disposed between the titanium alloy and the titanium nitride.

18. The apparatus of claim 16, wherein the first conductive material comprises a titanium nitride and the second conductive material comprises tungsten.

19. The apparatus of claim 16, further comprising:
a layer of silicon oxycarbonitride (SiOCN) disposed within the oxide material and above the first conductive material, the second conductive material, and the conductive tiers, wherein the bit line contact extends through the layer of SiOCN to contact the second conductive material.

20. The apparatus of claim 16, wherein the bit line contact comprises a conductive pillar comprising a third conductive material that is separated from the second conductive material by a fourth conductive material, the apparatus further comprising:
dielectric tiers disposed in between the conductive tiers and at least partially surrounding the pillar of poly material.
